(19) United States
(12) Patent Application Publication
(10) Pub. No.: US 2026/0034600 A1
(43) Pub. Date: Feb. 5, 2026

(54) BACKFLOW SOLDERING FURNACE SUPPORT ASSEMBLY

(71) Applicant: Illinois Tool Works Inc., Glenview, IL (US)

(72) Inventor: Yuhua NI, Suzhou New District Jiangsu (CN)

(21) Appl. No.: 18/997,299

(22) PCT Filed: Jul. 6, 2023
(86) PCT No.: PCT/US2023/069683

§ 371 Date: Jan. 21, 2025

(30) Foreign Application Priority Data
Jul. 22, 2022 (CN) 202210866599.1

(51) Int. Cl. B23K 3/08; B23K 1/00; B23K 1/008; B23K 101/42

(52) U.S. Cl. CPC B23K 3/087; B23K 1/0008; B23K 1/008; B23K 2101/42

(57) ABSTRACT

The present application provides a reflow oven support assembly, comprising a fixture (301), a support rod (302) and an adjustment device (303), the fixture (301) being connected to one of the upper furnace chamber housing (101) and lower furnace chamber housing (102) of the reflow oven; a first end of the support rod (302) being connected to the other of the upper furnace chamber housing (101) and lower furnace chamber housing (102); the adjustment device (303) being connected to a second end of the support rod (302) and connected to the fixture (301), in which the adjustment device (303) is disposed to be adjustable relative to the fixture (301) and the adjustment device (303) is capable of being connected to different positions of the fixture (301). The reflow oven support assembly in the present application is adjustable within a certain range to accommodate to the shape of the upper furnace chamber housing.

### TECHNICAL FIELD

The present application relates to a reflow oven support assembly, in particular to a support structure for supporting the upper furnace chamber housing of the reflow oven.

### BACKGROUND

Reflow ovens are commonly used to achieve surface soldering processes for printed circuit boards (PCBs). The reflow oven comprises an upper furnace chamber housing, a lower furnace chamber housing, and the upper furnace chamber housing and lower furnace chamber housing jointly form a working space of the reflow oven. Printed circuit boards (PCB) are heated in the working space of the reflow oven. The upper furnace chamber housing of the reflow oven is disposed to be openable to facilitate repair. The support structure is used to support the upper furnace chamber housing when the reflow oven is open.

### SUMMARY

The present application provides a reflow oven support assembly, comprising a fixture, a support rod and an adjustment device, the fixture being connected to one of the upper furnace chamber housing and lower furnace chamber housing of the reflow oven; a first end of the support rod being connected to the other of the upper furnace chamber housing and lower furnace chamber housing; the adjustment device being connected to a second end of the support rod and connected to the fixture, in which the adjustment device is disposed to be adjustable relative to the fixture and the adjustment device is capable of being connected to different positions of the fixture.

According to the above reflow oven support assembly, the adjustment device comprises at least one fastener and adjustment block, the adjustment block being connected to the fixture by at least one fastener.

According to the above reflow oven support assembly, one of the adjustment device and the fixture comprises at least one adjustment portion, the at least one fastener being movable in the at least one adjustment portion, such that the adjustment block is capable of being fixed to different positions of the fixture.

According to the above reflow oven support assembly, the fixture comprises a pair of side walls that each have at least one adjustment portion, the adjustment portion being a slot that traverses a respective one of the pair of side walls, and the adjustment block being disposed between the pair of side walls.

The reflow oven support assembly further comprises an adjustment block support seat, which comprises a substrate and a support column, the substrate being connected to the fixture and positioned on a side of the adjustment block away from the support rod; the support column traverses the substrate and is capable of abutting against the adjustment block, the support column is capable of being adjustably connected to the substrate such that the support column is capable of supporting the adjustment block.

According to the above reflow oven support assembly, a second end of the support rod is configured to be capable of moving relative to the adjustment device within a certain range.

According to the above reflow oven support assembly, the reflow oven support assembly further comprises a support rod shaft connected to one of the support rod and the adjustment device, the other of the adjustment device and the support rod having a shaft mounting bore, the support rod being capable of passing through the shaft mounting bore to connect the support rod to the adjustment device and being capable of moving within the shaft mounting bore, such that the second end of the support rod is capable of moving relative to the adjustment device within a certain range.

According to the above reflow oven support assembly, the length of the support rod is adjustable, and the support rod is detachably mounted to the upper furnace chamber housing or lower furnace chamber housing of the reflow oven.

According to the above reflow oven support assembly, the reflow oven support assembly is configured to have the support rod abut against the adjustment device when the upper furnace chamber housing is open, such that the upper furnace chamber housing is supported; the support rod is in a free state relative to the adjustment device when the upper furnace chamber housing is closed.

The present application further provides a reflow oven, comprising: at least one pair of side support assemblies, and at least one intermediate support assembly, in which the at least one pair of side support assemblies and the at least one intermediate support assembly are arranged side by side in the length direction of the reflow oven and the at least one intermediate support assembly is arranged between at least one pair of side support assemblies, in which each of the pair of side support assemblies or each of the at least one intermediate support assembly is the above support assembly.

The support assembly in the present application is used to support the upper furnace chamber housing and arrange the plurality of support assemblies in the length direction of the reflow oven when the upper furnace chamber housing of the reflow oven is open. The upper furnace chamber housing of the reflow oven is typically disposed with a certain bend amount at the time of manufacture to accommodate the deformation resulting from heating during operation. In order to ensure that the upper furnace chamber housing is uniformly stressed when supported by the plurality of support assemblies, the plurality of support assemblies needs to be of different lengths. The support assemblies in the present application is capable of being adjusted within a certain range to accommodate the bent portion of the upper furnace chamber housing.

### BRIEF DESCRIPTION OF THE DRAWINGS

FIG. 1A is a perspective view of a reflow oven according to an example of the present application when closed;

FIG. 1B is a perspective view of the reflow oven in FIG. 1A when open;

FIG. 2A is a schematic diagram of a reflow oven in the cold state according to the present application;

FIG. 2B is a schematic diagram of a reflow oven in the hot state according to the present application;

FIG. 3A is a perspective view of the support assembly in FIG. 1B;

FIG. 3B is an exploded view of the support assembly in FIG. 3A;

FIG. 4 is a perspective view of a support rod in the present application;

FIG. 5 is a perspective view of the adjustment block in FIG. 1B;

FIG. 6A is a perspective view of a fixture in the present application;

FIG. 6B is a perspective view of another angle of the fixture in FIG. 6A;

FIG. 7A is aside view of the support assembly in FIG. 3A when the upper furnace chamber housing is closed;

FIG. 7B is aside view of the support assembly in FIG. 3A when the upper furnace chamber housing is open;

FIG. 8A is aside view of the reflow oven in FIG. 1B;

FIG. 8B is a cross-sectional view of the reflow oven in FIG. 8A.

### DETAILED DESCRIPTION

Various specific embodiments of the present application will be described below with reference to the attached drawings that form a part of the present specification. It should be understood that while terms denoting orientation, such as “front,” “rear,” “upper,” “lower,” “left,” “right,” etc., are used in the present application to describe various exemplary structural parts and elements of the present application, these terms are used herein for convenience of illustration only and are determined based on the exemplary orientations shown in the attached drawings. Since the examples disclosed in the present application may be disposed in different orientations, these terms denoting orientation are for illustrative purposes only and should not be considered as limiting.

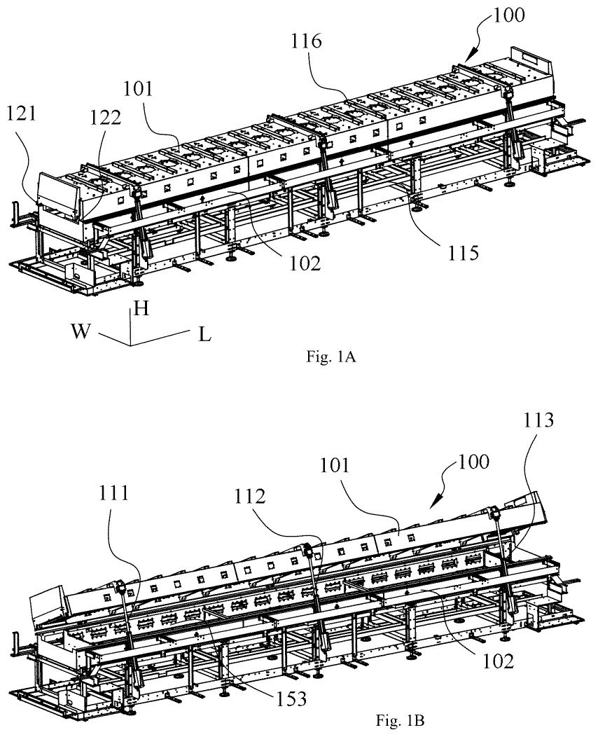

FIG. 1A is a perspective view of a reflow oven according to an example of the present application when closed, and FIG. 1B is a perspective view of the reflow oven in FIG. 1A when open. As shown in FIG. 1A, the reflow oven 100 comprises a bracket 115 and a reflow oven furnace chamber body 116, the latter being supported by the bracket 115. The reflow oven furnace chamber body 116 is generally rectangular in shape and has a length direction L, a height direction H and a width direction W. The reflow oven furnace chamber body 116 comprises an upper furnace chamber housing 101 and a lower furnace chamber housing 102. The upper furnace chamber housing 101 is located above the lower furnace chamber housing 102 and disposed opposite to each other to together form a furnace chamber containing space 153. The upper furnace chamber housing 101 and lower furnace chamber housing 102 together form a furnace chamber containing space 153. The furnace chamber containing space 153 is used to accommodate a printed circuit board (PCB) to be soldered and a transmission device for carrying and transferring the printed circuit board (PCB). In which, in the width direction W of the reflow oven furnace chamber body 116, the upper furnace chamber housing 101 has opposing first and second sides 121, 122, the first side 121 being pivotally connected to the lower furnace chamber housing 102. When the reflow oven is in need of cleaning and maintenance, etc., the second side 122 may be pushed upwards to open the upper furnace chamber housing 101 from above the lower furnace chamber housing 102.

As shown in FIG. 1B, the upper furnace chamber housing 101 and the lower furnace chamber housing 102 may be movably connected, the bracket 115 and the lower furnace chamber housing 102 are fixedly connected, and three support assemblies 111, 112, and 113 are provided between the bracket 115 and the upper furnace chamber housing 101. The three support assemblies 111, 112, and 113 each have one end connected to the upper furnace chamber housing 101 and the other end of each of the support assemblies 111, 112, and 113 is connected to the bracket 115. The bracket 115 and the lower furnace chamber housing 102 are fixedly connected, such that the other end of each of the support assemblies 111, 112, and 113 is connected to the lower furnace chamber housing 102 through the bracket 115. That is, the three support assemblies 111, 112, and 113 are connected to the upper furnace chamber housing 101 and lower furnace chamber housing 102, respectively. The three support assemblies 111, 112, and 113 are used to provide support between the upper furnace chamber housing 101 and lower furnace chamber housing 102.

The three support assemblies 111, 112, and 113 are connected to the first side 121 of the upper furnace chamber housing 101 and when the upper furnace chamber housing 101 is open, the three support assemblies 111, 112, and 113 are capable of supporting the upper furnace chamber housing 101 for it to remain open. The three support assemblies 111, 112, and 113 are arranged along the length direction of the reflow oven. The support assemblies 111 and 113 are respectively proximate to both ends of the length direction of the reflow oven and are side support assemblies; the support assembly 112 is located in the middle of the length direction of the reflow oven and is the intermediate support assembly.

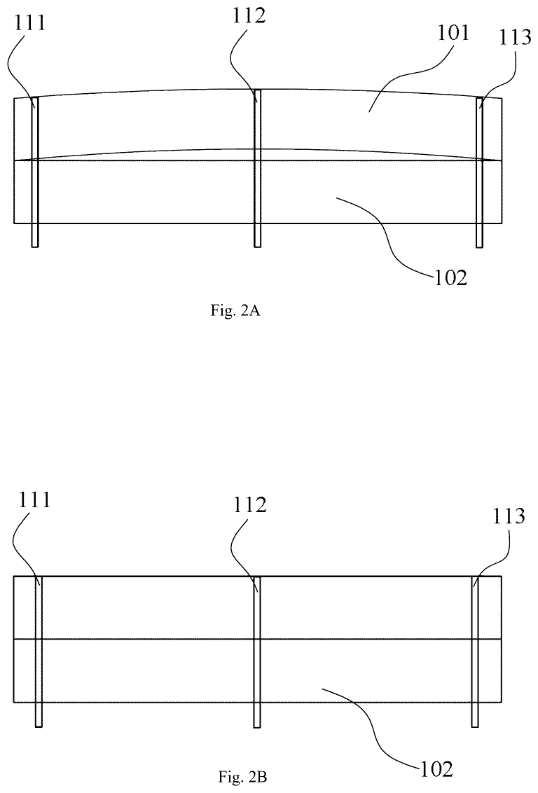

FIG. 2A is a schematic diagram of a reflow oven in the cold state according to the present application and FIG. 2B is a schematic diagram of a reflow oven in the hot state according to the present application.

The reflow oven is at a higher temperature when in operation, i.e., in the hot state; the reflow oven is at the same temperature as ambient temperature when not in operation, i.e., in the cold state. Due to the principles of thermal expansion, the shape of the upper furnace chamber housing 101 and the lower furnace chamber housing 102 differs in the cold state and the hot state. In order to ensure that the reflow oven is sealed in the hot state, the reflow oven is designed to have a certain deformation quantity reserved for the shape of the upper furnace chamber housing 101 of the reflow oven when in the cold state, such that it reaches the optimum shape when in the hot state. Specifically, as shown in FIG. 2A, the upper furnace chamber housing 101 is a slightly upwardly curved arc in the length direction when in the cold state, with the middle of the upper furnace chamber housing 101 being slightly higher than both ends. As shown in 2B, the upper furnace chamber housing 101 in the hot state is generally horizontal in the length direction and the height of each portion of the upper furnace chamber housing 101 is generally the same.

When the reflow oven is closed, the upper furnace chamber housing 101 is press fit on the lower furnace chamber housing 102 with its own weight, and the support assemblies 111, 112, and 113 are not supportive of the upper furnace chamber housing 101. When the upper furnace chamber housing 101 is open, the support assemblies 111, 112, and 113 support the upper furnace chamber housing 101. The reflow oven only opens for the upper furnace chamber housing 101 to be repaired when in the cold state. The height of the upper furnace chamber housing 101 in the middle of the cold state is greater than the height of both ends. Therefore, the overall length of the intermediate support assembly 112 needs to be slightly longer than the length of the side support assemblies 111 and 113 to allow the support assemblies 111, 112 and 113 to support the upper furnace chamber housing evenly. When processing the upper furnace chamber housing 101, the bend amount of the upper furnace chamber housing 101 cannot be precisely controlled due to process conditions, and when mounting the support assemblies 111, 112, and 113, the length of one or more of the support assemblies 111, 112, and 113 needs to be adjusted to match the bend amount of the upper furnace chamber housing 101, such that the support assemblies are uniformly stressed when supporting the upper furnace chamber housing 101. In one example of the present application, the intermediate support assembly 112 is disposed as a length-adjustable support assembly. In other examples of the present application, all of the support assemblies, or side support assemblies, may also be disposed as length-adjustable support assemblies.

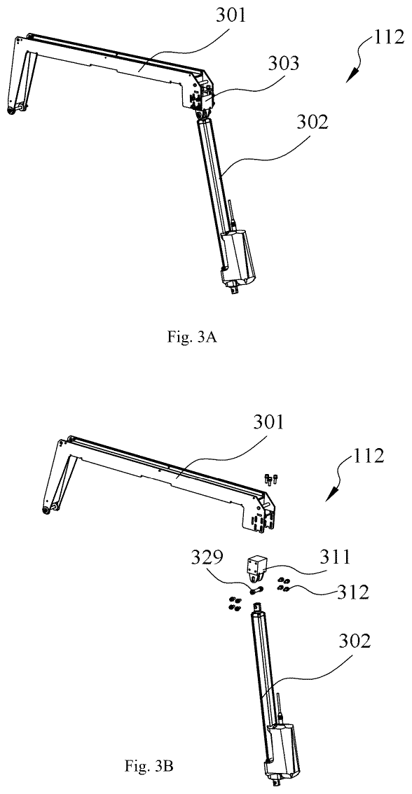

FIG. 3A is a perspective view of the support assembly in FIG. 1B and FIG. 3B is an exploded view of the support assembly in FIG. 3A. FIGS. 3A and 3B show the structure of the intermediate support assembly 112 in FIG. 1B. As shown in FIGS. 3A and 3B, the support assembly 112 comprises a fixture 301, a support rod 302, and an adjustment device 303. The fixture 301 is connected to the upper furnace chamber housing 101 and one end of the support rod 302 is connected to the lower furnace chamber housing 102. The adjustment device 303 is disposed between the support rod 302 and the fixture 301. The adjustment device 303 may be movably connected to the support rod 302 through the first support rod shaft 329 and is movable relative to the support rod 302 within a certain range. The adjustment device 303 comprises an adjustment block 311 and fasteners 312, the adjustment block 311 being fixedly connected to the fasteners 312 and the fixture 301. The relative position between the adjustment block 311 and the fixture 301 may be adjusted within a certain range prior to fixed connection through the fasteners 312. In one example of the present application, the support rod 302 is detachably connected to the lower furnace chamber housing 102 for ease of replacement of the support rod.

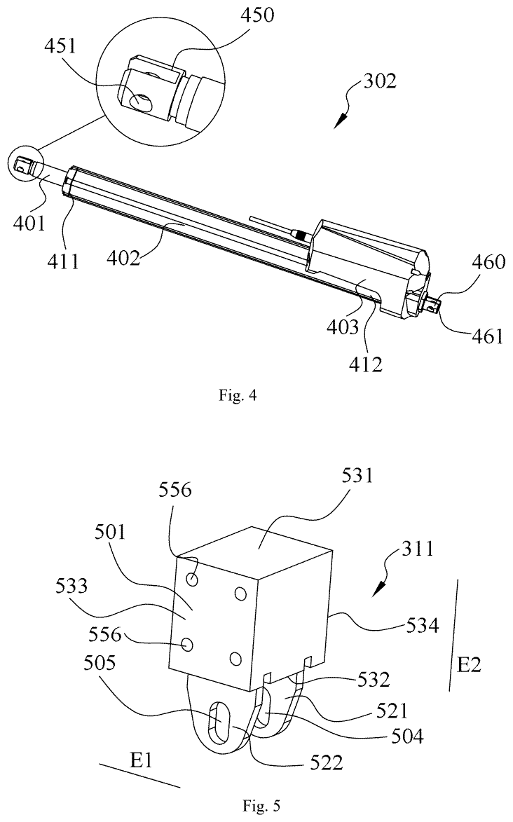

FIG. 4 is a perspective view of the support rod 302 in the present application illustrating the structure of the support rod. As shown in FIG. 4, the support rod 302 comprises a first rod 401, a second rod 402, and a length-adjustment mechanism 403. The second rod 402 has a first end 411 and a second end 412. The first rod 401 is sleeved in the second rod 402 and extends from the first end 411. The first rod 401 is movable relative to the second rod 402 along the axial direction of the support rod 302, changing the length of the support rod 302. The second end 412 of the second rod 402 is provided with a length-adjustment mechanism 403, which is connected to a control system of the reflow oven and is capable of receiving signals from the control system, thereby driving movement of the first rod 401 relative to the second rod 402 such that the support rod 302 reaches a predetermined length. In one example of the present application, the support rod 302 is a screw assembly. The second end 412 of the second rod 402 forms a first end of the support rod 302 and the distal end of the first rod 401 forms a second end of the support rod 302.

The distal end of the first rod 401 has a first support rod shaft mounting portion 450, which has a through hole 451 that traverse the first rod 401 along the radial direction of the support rod for mounting the first support rod shaft 329. The first rod 401 is connected to the adjustment device 303 through the first support rod shaft 329. The first rod 401 and first support rod shaft 329 are fixedly connected such that the first support rod shaft 329 is capable of moving together with the first rod 401. In another example of the present application, the first support rod shaft mounting portion 450 may also be disposed on the support rod 302, the first support rod shaft 329 being fixedly connected to the adjustment device 303.

Similarly, the second end 412 of the second rod 402 has a second support rod shaft mounting portion 460, which has a through hole 461 that traverses the second rod 402 along the radial direction of the support rod. The second rod 402 is connected to the bracket 115 through the second support rod shaft and the second rod 402 is capable of rotating at an angle relative to the bracket 115.

FIG. 5 is a perspective view of the adjustment block in FIG. 1B. As shown in FIG. 5, the adjustment block 311 comprises a body portion 501 and a pair of ear portions 521 and 522. The body portion 501 is generally a cube and has a top surface 531 and bottom surface 532 disposed opposite to each other, and a left side 533 and a right side 534 disposed opposite to each other. For ease of illustration, the direction perpendicular to the left side 533 is referred to as the first direction E1 of the adjustment block 311, and the direction perpendicular to the top surface 531 is referred to as the second direction E2 of the adjustment block 311. The left side 533 and right side 534 each have four mounting bores 556 for receiving fasteners 312. In one example of the present application, the mounting bores 556 are threaded holes and the fasteners 312 are screws.

The pair of ear portions 521 and 522 extend downwards along the second direction from the bottom surface 532 of the body portion 501. Each of the ear portions 521 and 522 is generally a sheet. There is a spacing between the ear portions 521 and 522, which is capable of accommodating the first support rod shaft mounting portion 450. The shaft mounting bores 504 and 505 are provided on the ear portions 521 and 522, respectively. The shaft mounting bores 504 and 505 are shaped as waist-shaped holes. The width of the shaft mounting bores 504 and 505 in the first direction is smaller than the length in the second direction, the width of the shaft mounting bores 504 and 505 in the first direction is equal to or slightly greater than the outer diameter of the first support rod shaft 329, such that the first support rod shaft 329 is able to enter the shaft mounting bores 504 and 505 and move a certain distance along the second direction. The length in the second direction of the shaft mounting bores 504 and 505 is disposed to be greater than a size range in which the corresponding position of the upper furnace chamber housing is capable of deformation.

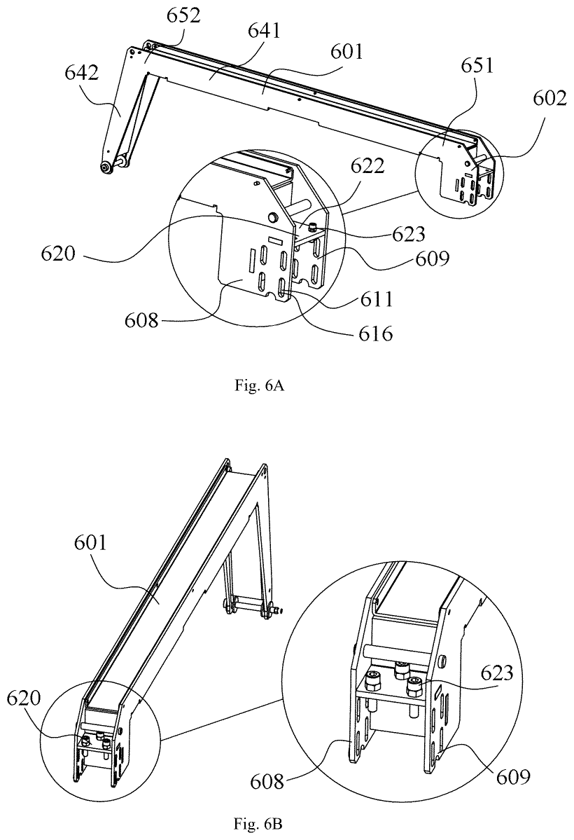

FIG. 6A is a perspective view of a fixture in the present application, and FIG. 6B is a perspective view of another angle of the fixture in FIG. 6A. As shown in FIGS. 6A and 6B, the fixture 301 comprises a housing connection 601 and an adjustment device connection 602. The housing connection 601 comprises a rod portion 641 and an extension portion 642. The rod portion 641 is generally long strip-like and has a first end 651 and a second end 652, the first end 651 being connected to the adjustment device connection 602, and the second end 652 being connected to the extension portion 642. In which, the rod portion 641 is arranged along the width direction of the reflow oven 100 and is connected to the top of the upper furnace chamber housing. The extension portion 642 extends from the second end 652 of the rod portion 641, and the extension portion 642 is connected to the first side 121 of the upper furnace chamber housing 101. The included angle between the extension portion 642 and the rod portion 641 is configured to match the shape of the upper furnace chamber housing 101. The adjustment device connection 602 is adjacent to the second side 122 of the upper furnace chamber housing 101.

The adjustment device connection 602 comprises a pair of side walls 608 and 609 disposed opposite to each other, which are arranged along the length direction of the reflow oven 100, and there is a spacing between the side walls 608 and 609, which is capable of accommodating the adjustment block 311. Each of the side walls 608 and 609 comprises four slots 616 that traverse the respective side wall. The slots 616 are long bars and extend generally along the height direction of the reflow oven. The slots 616 form the adjustment portions 611, the fasteners 312 of the adjustment device 303 are capable of passing through the adjustment portions 611 and are capable of moving in the adjustment portions 611 along the extension direction of the bar-shaped slots 616. The fasteners 312 move in the adjustment portions 611 and are able to adjust the position of the adjustment block 311 relative to the adjustment device connection 602. In another example of the present application, the adjustment portions 611 are disposed on the adjustment device 303, and the adjustment portions 611 are bar-shaped recesses formed from the inward recess from an outer surface of the adjustment block 311, and the fasteners 312 are capable of moving in the recess.

The support assembly also comprises an adjustment block support seat 620 disposed between the pair of side walls 608 and 609. The adjustment block support seat 620 is located above the adjustment block 311 along the height direction of the reflow oven. The adjustment block support seat 620 comprises a substrate 622 and a support column 623, with both ends of the substrate 622 being connected to the pair of side walls 608 and 609, respectively. The support column 623 is capable of passing through the substrate 622 and is adjustable relative to the substrate 622. The support column 623 is capable of adjusting the length of the extended substrate 622 portion for abutting against the adjustment block 311. In one example of the present application, the support column 623 is a screw and the substrate 622 is provided with a threaded hole thereon that mates therewith.

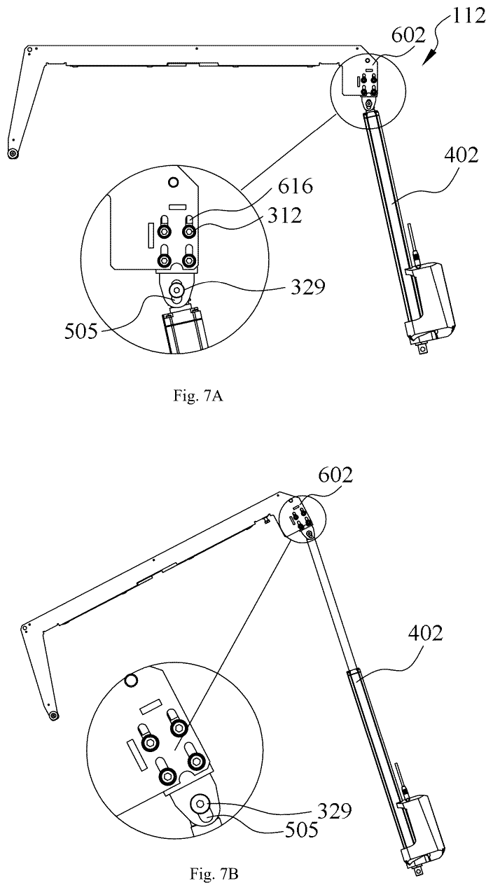

FIG. 7A is a side view of the support assembly in FIG. 3A when the upper furnace chamber housing is closed and FIG. 7B is a side view of the support assembly in FIG. 3A when the upper furnace chamber housing is open.

As shown in FIGS. 3A, 3B, 7A, and 7B, the adjustment device 303 in the present application is disposed to be adjustable relative to the fixture 301 and the adjustment device 303 is capable of being connected to different positions of the fixture 301. That is, prior to the adjustment device 303 being fastened and connected to the fixture 301, the adjustment device 303 is movable relative to the fixture 301 and the adjustment device 303 remains in a respective position relative to the fixture 301 after the adjustment device 303 is fastened and connected to the fixture 301.

When the support assembly 112 is mounted to the reflow oven, it is necessary to adjust the relative position of the adjustment block 311 and the adjustment device connection 602 according to the deformation quantity of the upper furnace chamber housing 101. The fasteners 312 are first inserted through the slots 616 into the mounting bores 556 of the adjustment block 311. The fasteners 312 are able to slide in the slots 616, then the adjustment block 311 is adjusted to the appropriate position and the fasteners 312 are rotated to tighten the adjustment block 311, such that it cannot be moved relative to the adjustment device connection 602. In one example of the present application, the fasteners 312 are located in a position proximate below the slots 616.

In conjunction with FIGS. 3A, 6A, 7A and 7B, the support column 623 is configured to abut against the top surface 531 of the adjustment block 311 to further prevent the adjustment block 311 from being moved upwardly by pressure of the support rod 302. The adjustment device 303 is fixed in a particular position by the fasteners 312 and support column 623, and is unable to move relative to the adjustment device connection 602. In the present application, the adjustment device 303 is used to accommodate different deformation quantities of the respective upper furnace chamber housing 101, such that further adjustment is not required after assembly unless the relative position changes. In one example of the present application, the adjustment device 303 is capable of being adjusted within a range of −5-12 mm.

The first support rod shaft 329 is located in the shaft mounting bore 505 and is capable of moving and rotating in the shaft mounting bore 505. When the upper furnace chamber housing is open, the first support rod shaft 329 abuts against the top of the shaft mounting bore 505 and the support rod 302 provides support for the upper furnace chamber housing 101. When the upper furnace chamber housing 101 is closed and in the hot state, the upper furnace chamber housing 101 is subjected to thermal deformation, in which the middle portion is flush or largely flush with the ends. The upper furnace chamber housing 101 is press fit on the lower furnace chamber housing 102 with its own weight to form a seal with the lower furnace chamber housing 102, and the support rod 302 no longer provides support for the upper furnace chamber housing 101. At this point, the first support rod shaft 329 exits the top of the shaft mounting bore 505 and moves down a distance that is located in the middle or bottom of the shaft mounting bore 505. The shaft mounting bore 505 is disposed in a way that allows the first support rod shaft 329 to move in the shaft mounting bore 505, such that the support rod 302 is able to support the upper furnace chamber housing 101 when the upper furnace chamber housing 101 is open and be in a free state when the upper furnace chamber housing 101 is closed and no longer supports the upper furnace chamber housing 101. The free state of the support rod 302 refers to the absence of an interaction along the axial direction between the support rod 302 and the adjustment device 303; hence, the support rod 302 is not supportive.

The ends of the support rod 302 are rotatably connected to the upper furnace chamber housing 101 and the bracket 115 by a shaft, respectively, and the angle of the support rod 302 relative to the upper furnace chamber housing 101 and the bracket 115 may vary.

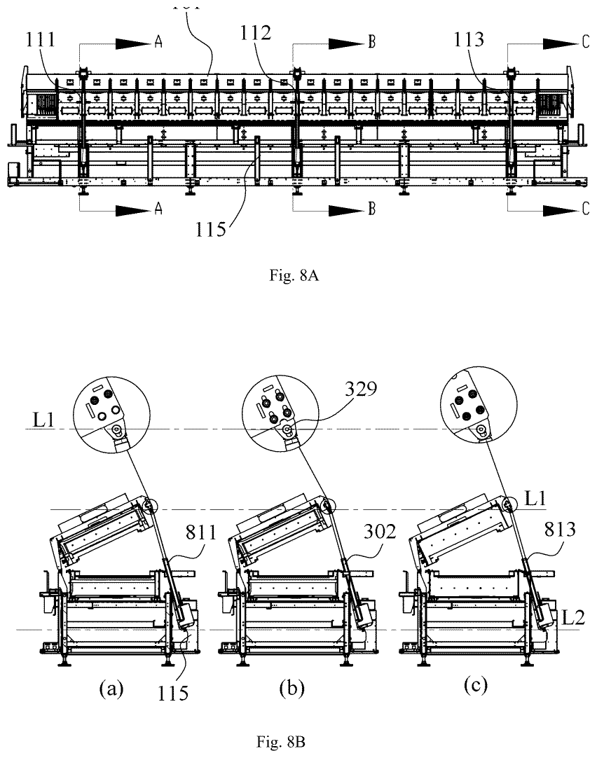

FIG. 8A is a side view of the reflow oven of FIG. 1B, and FIG. 8B is a cross-sectional view of the reflow oven in FIG. 8A, in which portion (a) corresponds to the A-A section line, portion (b) corresponds to the B-B section line, and portion (c) corresponds to the C-C section line. The A-A section line, B-B section line, and C-C section line correspond to the support assemblies 111, 112, and 113, respectively.

In the present application, the support rods 811, 302 and 813 for each of the support assemblies 111, 112, and 113 have the same specification, and each support rod has a length-adjustment mechanism connected to a control system, which issues signals to the adjustment mechanism such that the three support rods move synchronously. When open, as shown in FIG. 8B, the support rods 811, 302 and 813 have the same length, the center of the first support rod shaft of the support rods 811, 302 and 813 being on the same horizontal line L1 and the center of the second support rod shaft being on one horizontal line L2. The support rods 811, 302, and 813 have the same tilt angle relative to the bracket 115, such that the upper furnace chamber housing 101 is uniformly stressed in the width direction. In the present application, the use of the same support rods 811, 302 and 813 facilitates the control of the synchronous movements of the three support rods and ensures that the rods are at the same tilt angle relative to the bracket 115. Therefore, to accommodate the deformation reserved by the upper furnace chamber housing 101, it is desirable to dispose one or more of the support assemblies 111, 112, and 113 to be adjustable in length. In one example of the present application, the length of the intermediate support assembly 112 is adjustable and the length of the side support assemblies 111 and 113 is not adjustable. In another example of the present application, the length of the side support assemblies 111 and 113 is adjustable and the length of the intermediate support assembly 112 is not adjustable.

With reference to FIGS. 7A, 7B, and 8, in the present application, the relative positions of the respective adjustment blocks 311 of the support assemblies 111, 112, and 113 to the adjustment device connection 602 are different. Therefore, the relative position of the first support rod shaft 329 in the shaft mounting bore 505 is different when the upper furnace chamber housing 101 is closed. However, the support rod of each of the support assemblies 111, 112, and 113 is in a free state and no longer supports the upper furnace chamber housing.

In another example of the present application, the support rod of each of the support assemblies 111, 112, and 113 may also be connected to the upper furnace chamber housing, with the fixture being connected to the lower furnace chamber housing.

The length-adjustable support assemblies in the present application are capable of accommodating the bend amount reserved by the upper furnace chamber housing for possible deformation in the hot state, such that the upper furnace chamber housing is uniformly supported when the upper furnace chamber housing is open. Particularly in some longer reflow ovens, uniformly supporting the upper furnace chamber housing may extend the service life of the support assembly. In one example of the present application, the length of the reflow oven is not less than 5 m. When the reflow oven is longer, more support assemblies may be disposed to support the upper furnace chamber housing and length-adjustable support assemblies may be disposed according to the degree of bending of the upper furnace chamber housing.

Although the present disclosure has been described in connection with examples of the embodiment outlined above, various alternatives, modifications, variations, improvements, and/or substantial equivalents, whether known or foreseeable now or in the near future, may be apparent to those having at least ordinary skill in the art. In addition, the technical effects and/or technical problems described in the present specification are exemplary and not limiting; therefore, the disclosure in the present specification may be used to solve other technical problems and have other technical effects and ┌text cut-off┐ Therefore, examples of the present disclosure as set forth above are intended to be illustrative and not limiting. Various changes may be made without departing from the spirit or scope of the present disclosure. Therefore, the present disclosure is intended to include all known or earlier developed alternatives, modifications, variations, improvements and/or substantial equivalents.

What is claimed is:

1. A reflow oven support assembly, wherein comprising
a fixture (301), connected to one of the upper furnace chamber housing (101) and lower furnace chamber housing (102) of the reflow oven;
a support rod (302), which first end is connected to the other of the upper furnace chamber housing (101) and lower furnace chamber housing (102);
an adjustment device (303), connected to a second end of the support rod (302) and connected to the fixture (301), in which the adjustment device (303) is disposed to be adjustable relative to the fixture (301) and the adjustment device (303) is capable of being connected to different positions of the fixture (301).

2. The reflow oven support assembly according to claim 1, wherein
the adjustment device (303) comprises at least one fastener (312) and adjustment block (311), the adjustment block (311) being connected to the fixture (301) by at least one fastener (312).

3. The reflow oven support assembly according to claim 2, wherein
one of the adjustment device (303) and the fixture (301) comprises at least one adjustment portion (611), the at least one fastener (312) being movable in the at least one adjustment portion (611), such that the adjustment block (311) is capable of being fixed to different positions of the fixture (301).

4. The reflow oven support assembly according to claim 3, wherein
the fixture (301) comprises a pair of side walls (608, 609) that each have at least one adjustment portion (611), the adjustment portion (611) being a slot that traverses a respective one of the pair of side walls (608, 609), and the adjustment block (311) being disposed between the pair of side walls (608, 609).

5. The reflow oven support assembly according to claim 3, wherein further comprising
an adjustment block support seat (620), which comprises a substrate (622) and a support column (623), the substrate (622) being connected to the fixture (301) and located on a side of the adjustment block (311) away from the support rod (302); the support column traverses the substrate (622) and is capable of abutting against the adjustment block (311), and the support column (623) is capable of being adjustably connected to the substrate (622) such that the support column (623) is capable of supporting the adjustment block (311).

6. The reflow oven support assembly according to claim 1, wherein
a second end of the support rod (302) is configured to be capable of moving relative to the adjustment device (303) within a certain range.

7. The reflow oven support assembly according to claim 6, wherein
the reflow oven support assembly further comprises a support rod shaft (329) connected to one of the support rod (302) and the adjustment device (303), the other of the adjustment device (303) and the support rod (302) having a shaft mounting bore (505), the support rod (329) being capable of passing through the shaft mounting bore (505) to connect the support rod (302) to the adjustment device (303) and being capable of moving within the shaft mounting bore (505), such that the second end of the support rod (302) is capable of moving relative to the adjustment device (303) within a certain range.

8. The reflow oven support assembly according to claim 1, wherein
the length of the support rod is adjustable, and the support rod is detachably mounted to the upper furnace chamber housing or lower furnace chamber housing of the reflow oven.

9. The reflow oven support assembly according to claim 6, wherein
the reflow oven support assembly is configured to have the support rod (302) abut against the adjustment device when the upper furnace chamber housing is open, such that the upper furnace chamber housing is supported; the support rod (302) is in a free state relative to the adjustment device when the upper furnace chamber housing is closed.

10. A reflow oven, wherein comprising
at least one pair of side support assemblies, and
at least one intermediate support assembly,
in which the at least one pair of side support assemblies and the at least one intermediate support assembly are arranged side by side in the length direction of the reflow oven and the at least one intermediate support assembly is arranged between at least one pair of side support assemblies, in which each of the pair of side support assemblies or each of the at least one intermediate support assembly is the support assembly according to any one of claims 1-9.
